(19) United States
(12) Patent Application Publication
(10) Pub. No.: US 2025/0248158 A1
(43) Pub. Date: Jul. 31, 2025

(54) ELECTRONIC COMPONENT, SYSTEM, AND MOVING BODY

(71) Applicant: CANON KABUSHIKI KAISHA, Tokyo (JP)

(72) Inventor: YU KATASE, Kanagawa (JP)

(21) Appl. No.: 19/042,164

(22) Filed: Jan. 31, 2025

(30) Foreign Application Priority Data
Jan. 31, 2024 (JP) 2024-013305

(51) Int. Cl. H10F 39/00; H04N 23/63; H10F 39/95

(52) U.S. Cl. CPC H10F 39/8063; H04N 23/63; H10F 39/811; H10F 39/95

(57) ABSTRACT

An electronic component includes a substrate having a first surface, a circuit board having a second surface facing the first surface, and an optical member having a third surface facing the first surface. The first surface of the substrate has a central region where a plurality of elements are arranged, the second surface of the circuit board is arranged above the first surface so as not to cover the central region, the third surface of the optical member is arranged above the central region without intervening the circuit board so as to have a space between the first surface and the third surface, and a plurality of microlenses are arranged on the third surface of the optical member.

### BACKGROUND OF THE INVENTION

### Field of the Invention

The present disclosure relates to an electronic component, a system, and a moving body.

### Description of the Related Art

Electronic components that include a device including an element configured to receive light, such as an image capturing device, a device including an element configured to emit light, such as an OLED, or a device including an element configured to emit light, such as a Vertical Cavity Surface Emitting Laser (VCSEL), are widely used. For these electronic components, an arrangement in which an optical member is provided on the front surface of the device is widely used. Further miniaturization of the electronic component is demanded due to space constraints of a product on which the electronic component is mounted. Furthermore, if the optical member includes a microlens, it is demanded to highly accurately align the microlens with the element in clearance and position to condense light.

Japanese Patent Laid-Open No. 2002-299592 (patent literature 1) describes an arrangement in which a wiring plate with an opening is mounted on an image sensor, and a seal member (optical member) is mounted on the opening of the wiring plate.

Japanese Patent Laid-Open No. 2023-52615 (patent literature 2) describes an arrangement in which a surface emitting laser board is mounted on a mounting substrate, and an optical member is mounted on the surface emitting laser board.

Japanese Patent Laid-Open No. 2008-277593 (patent literature 3) describes an arrangement in which a resin base material embedded with a conductor (lead frame) and a transparent member (optical member) and integrally molded therewith is mounted on an optical element.

### SUMMARY OF THE INVENTION

According to one aspect of the present disclosure, there is provided an electronic component comprising a substrate having a first surface, a circuit board having a second surface facing the first surface, and an optical member having a third surface facing the first surface, wherein the first surface of the substrate has a central region where a plurality of elements are arranged, the second surface of the circuit board is arranged above the first surface so as not to cover the central region, the third surface of the optical member is arranged above the central region without intervening the circuit board so as to have a space between the first surface and the third surface, and a plurality of microlenses are arranged on the third surface of the optical member.

Further features of the present invention will become apparent from the following description of exemplary embodiments (with reference to the attached drawings).

### BRIEF DESCRIPTION OF THE DRAWINGS

FIGS. 1A and 1B are views showing the arrangement of an electronic component according to the first embodiment;

FIGS. 2A to 2C are views each exemplarily showing the arrangement pattern of an adhesive;

FIGS. 3A and 3B are views each showing an example of a resin filling the gap between an optical member and a circuit board;

FIGS. 4A to 4C are views each showing an example of the height relationship between the optical member and the circuit board;

FIGS. 5A and 5B are views showing the arrangement of an electronic component according to the second embodiment;

FIGS. 6A to 6C are views showing the arrangement of an electronic component according to the third embodiment;

FIGS. 7A to 7C are views showing the arrangement of an electronic component according to the third embodiment;

FIG. 8 is a view showing the arrangement of a system according to the fourth embodiment;

FIG. 9A is a view showing the arrangement of a system according to the fifth embodiment;

FIG. 9B is a view showing the arrangement of a moving body according to the fifth embodiment;

FIG. 10 is a view showing the arrangement of a system according to the sixth embodiment;

FIG. 11 is a view showing the arrangement of a system according to the seventh embodiment;

FIGS. 12A and 12B are views each showing the arrangement of a system according to the eighth embodiment;

FIGS. 13A and 13B are views showing the arrangement of a system according to the ninth embodiment; and

FIG. 14 is a view showing the arrangement of a system according to the tenth embodiment.

### DESCRIPTION OF THE EMBODIMENTS

In patent literature 1, the optical member is mounted on the wiring plate, so that there is room for improvement in miniaturization in the thickness direction. Further, the clearance between the image sensor and the optical member can cause variations in thickness of constituent members.

In patent literature 2, the optical member is mounted directly on the surface emitting laser board, but variations in thickness can occur due to solder bonding. Further, since the surface emitting laser board is mounted on the mounting substrate, if the mounting substrate and the surface emitting laser board warp when bonding them, height variations can occur in the surfaces thereof.

In patent literature 3, the transparent member (optical member) in the resin base material may warp due to integral molding, and height variations can occur in the surface thereof. Further, since this does not function as a circuit board including circuits in the both surfaces, it is necessary to prepare another circuit board, and there is room for improvement in miniaturization.

The present disclosure relates to a technique advantageous in achieving both miniaturization of an electronic component and highly accurate alignment between an element in a substrate and an optical member.

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

Note that in the following description and drawings, common reference numerals denote common components throughout a plurality of drawings. Hence, the common components will be described by cross-referring to the plurality of drawings, and a description of components denoted by common reference numerals will be omitted appropriately.

### First Embodiment

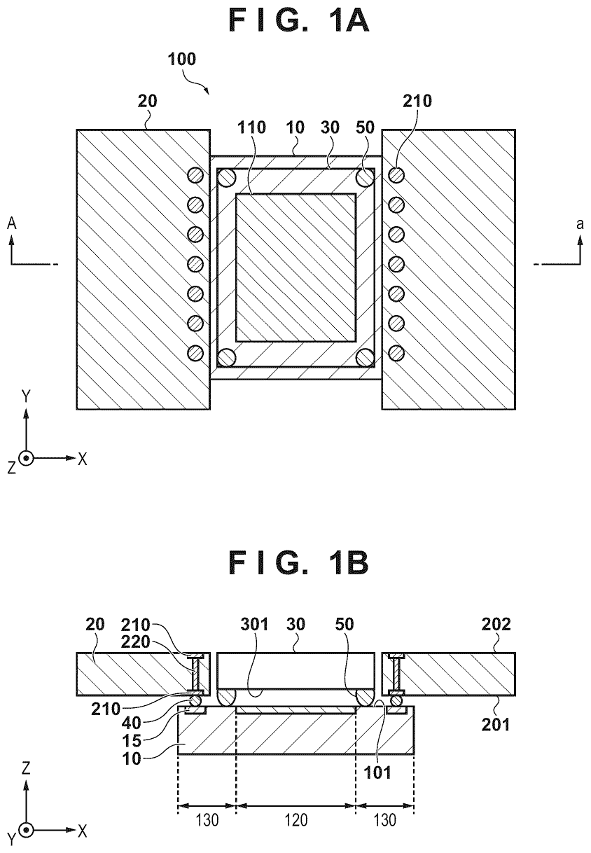

FIGS. 1A and 1B are views showing the arrangement of an electronic component 100 according to the first embodiment. FIG. 1A is a plan view of the electronic component 100, and FIG. 1B is a sectional view taken along a line A-a shown in FIG. 1A. In the specification and the accompanying drawings, directions will be indicated on an XYZ coordinate system in which a horizontal surface is defined as the X-Y plane. Here, a substrate 10 is placed such that the surface (first surface 101) thereof is parallel to the horizontal surface (X-Y plane). Accordingly, in the following description, directions orthogonal to each other within a plane along the surface of the substrate 10 will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

The electronic component 100 can include the substrate 10, and a circuit board 20 and an optical member 30 arranged on the substrate 10. The X direction and Y direction are directions parallel to the first surface 101 of the substrate 10. The Z direction is a direction perpendicular to the first surface 101. The size in the Z direction may be expressed as the “thickness”. Each of the typical substrate 10 and electronic component 100 has the Z-direction size smaller than the X-and Y-direction sizes, and has a substantially flat plate shape.

The type of the substrate 10 is not particularly limited, but typically a semiconductor substrate. In an example, the substrate 10 can mainly be the semiconductor substrate of an optical device such as an image capturing device, a display device, or a light-emitting device. The substrate 10 according to this embodiment can include a central region 120 and a peripheral region 130 located around the central region. A plurality of elements 110 are formed in an array in the first surface 101 in the central region 120. If the substrate 10 is the semiconductor substrate of an image capturing device, the element 110 is a light-receiving element. In this case, the element 110 can be, for example, a Single Photon Avalanche Diode (SPAD) sensor or a Complementary Metal Oxide Semiconductor (CMOS) sensor.

If the substrate 10 is the semiconductor substrate of a light-emitting device, the element 110 is a light-emitting element. In this case, the element 110 can be, for example, a Vertical Cavity Surface Emitting Laser (VCSEL). In the peripheral region 130, peripheral circuits (not shown) such as a driving circuit, a control circuit, a signal processing circuit, and an output processing circuit, and an electrode (first electrode 15) such as an input terminal or an output terminal are provided. Note that if the substrate 10 is a substrate in which two or more substrates are stacked, the substrate where the peripheral circuits are provided may be stacked below the central region 120.

The circuit board 20 is a substrate in which electrical circuits achieving various functions are mounted. The specific functions of the circuit board 20 can be functions of supplying a control signal or power to the element provided in the substrate 10, processing a signal output from the substrate 10, storing a signal, transmitting a signal to an external computer or a network, and the like. The circuit board 20 includes an electrode 210 (second electrode) in at least one of a second surface 201 facing the first surface 101 of the substrate 10 and an opposite surface 202 of the second surface 201. A plurality of electrodes 210 can be arranged. From the viewpoint to be described later, it is preferable that the electrodes 210 (second electrodes) are arranged in the second surface 201 of the circuit board 20, and the electrodes 210 (third electrodes) electrically connected to the second electrodes are arranged in the opposite surface 202. In this case, the electrode 210 in the second surface 201 and the electrode 210 in the opposite surface 202 can be interconnected by a wiring 220 (conductor) in the circuit board 20. For example, an electrode (not shown) provided in the peripheral region 130 of the first surface 101 of the substrate 10 and the electrode 210 provided in the second surface 201 of the circuit board 20 are arranged to face each other, and they are electrically connected via an electrically conductive member 40. With this, it is possible to perform input/output to/from the substrate 10 from both the first surface 201 and the opposite surface 202 of the circuit board 20, and the circuit board can be miniaturized by routing the wiring 220. For the electrically conductive member 40, for example, an Au bump or the like can be used. In order to avoid hindering the light reception, display, or light emission by the plurality of elements 110 formed in an array in the central region 120 in the first surface 101 of the substrate 10, the circuit board 20 is arranged so as not to cover at least the upper portion of the central region 120 of the substrate 10.

As for the connection between the substrate 10 and the circuit board 20, as shown in FIG. 1B, the electrically conductive member 40 can achieve both the electrical connection and the mechanical connection between the substrate 10 and the circuit board 20. Note that the mechanical strength may be supplemented by arranging an underfill agent or the like (not shown) around the electrically conductive member 40.

For the optical member 30, for example, a transparent member made of glass, silica glass, quartz or the like can be used. In accordance with the specifications of the electronic component 100, anti-reflection coating may be applied to the optical member 30. Alternatively, in accordance with the specifications of the electronic component 100, a member that easily transmits infrared light may be used for the optical member 30, or infrared protective coating may be applied to the optical member 30. The optical member 30 is mounted on the substrate 10. The optical member 30 has a third surface 301 facing the first surface 101 of the substrate 10. The third surface 301 of the optical member 30 is arranged above the central region without intervening the circuit board 20 so as to have a space between the first surface 101 of the substrate 10 and the third surface 301 of the optical member 30. In an example, the optical member 30 is mounted via an adhesive 50 so as to form a space between the first surface 101 of the substrate 10 and the third surface 301 of the optical member 30. In this case, the optical member 30 is mounted to cover at least the entire area of the upper portions of the plurality of elements 110 but not to cover the upper portion of the circuit board 20. The adhesive 50 may be arranged to bond the first surface 101 of the substrate 10 and the third surface 301 of the optical member 30 as shown in FIG. 1, or may be arranged between the circuit board 20 and the optical member 30. In order to provide a space between the first surface 101 and the third surface 301, it is easier to arrange the adhesive 50 between the first surface 101 and the third surface 301. In addition, in order to accurately form the spatial interval between the first surface 101 and the third surface 301, it is preferable to arrange the adhesive 50 between the first surface 101 and the third surface 301. One of reasons why the spatial interval between the first surface 101 and the third surface 301 is preferably formed to have a constant distance is that the accuracy and efficiency of light reception, display, or light emission of the element 110 can be improved. If the distance changes, the light reception amount, the light emission amount, or the like can change among the elements 110. In order to ensure that the space between the first surface 101 and the third surface 301 has the constant distance, the adhesive 50 more preferably contains a spacer of a uniform size. The distance between the first surface 101 and the third surface 301 is, for example, 10 μm or more and 200 μm or less, but an appropriate value can be selected in accordance with the size of the element or the like. The thickness of the optical member is, for example, about 0.2 mm to 1.0 mm. If the optical member is excessively thin, this can influence the strength and deformation. If the optical member is excessively thick, this can hinder miniaturization. A proper thickness is preferably selected in consideration of the thickness of the circuit board 20, the distance between the first surface 101 and the third surface 301, and the like.

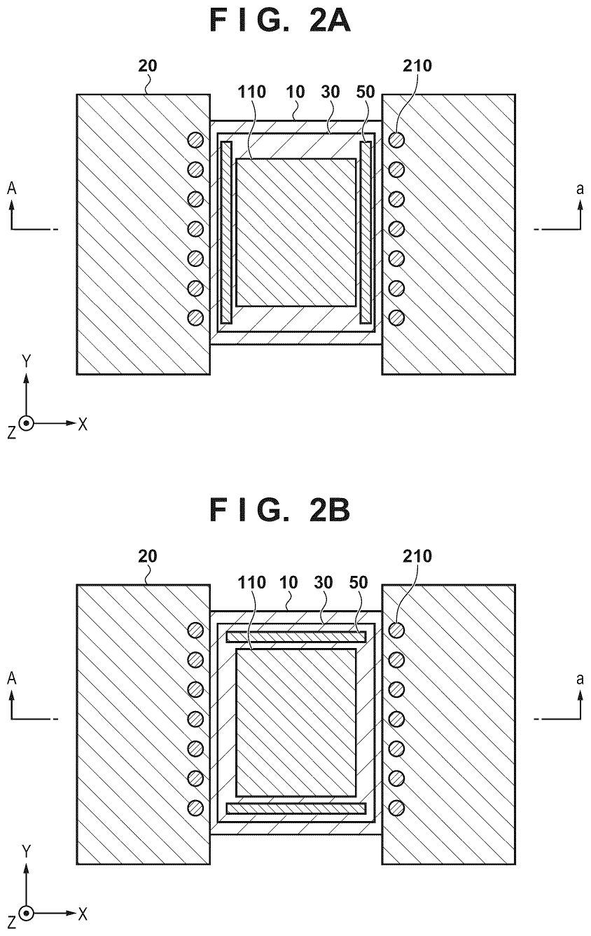

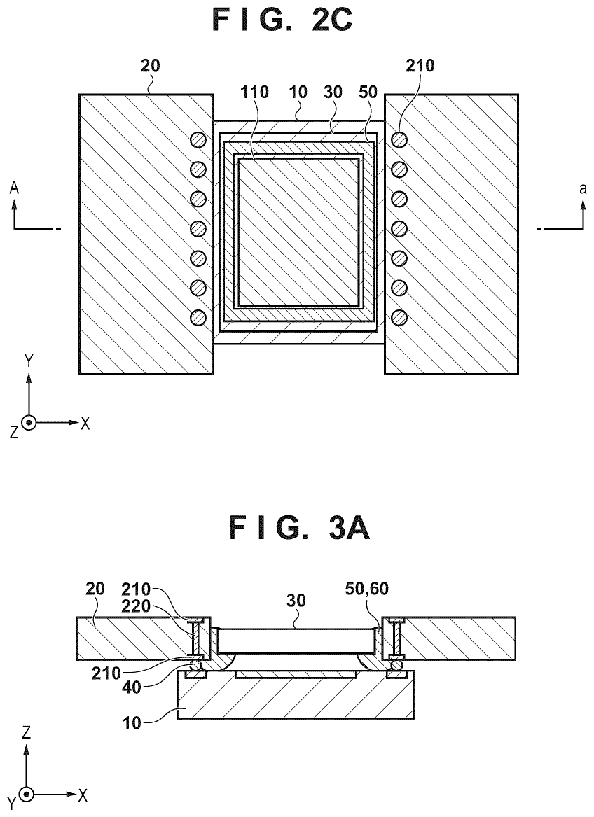

FIGS. 1A and 1B show an example in which the adhesive 50 is arranged at at least four locations (for example, positions of four corners of the third surface 301 of the optical member 30) scattered in the peripheral region 130 of the substrate 10. Each of FIGS. 2A to 2C is a plan view of the electronic component 100 similar to FIG. 1A but showing another example of the arrangement pattern of the adhesive 50. Here, considering the peripheral region 130 corresponding to the outer circumference of the optical member 30 as a quadrilateral shape, one long side of the four sides is defined as the first side, and the long side opposite to the first side is defined as the second side. Further, one short side of the four sides is defined as the third side, and the short side opposite to the third side is defined as the fourth side. FIG. 2A shows an example in which the adhesive 50 is arranged in the first region having a longitudinal length in a direction (Y direction) along the first side and in the second region having a longitudinal length in a direction (Y direction) along the second side. FIG. 2B shows an example in which the adhesive 50 is arranged in the third region having a longitudinal length in a direction (X direction) along the third side and in the fourth region having a longitudinal length in a direction (X direction) along the fourth side. FIG. 2C shows an example in which the adhesive 50 is arranged in the first, second, third, and fourth regions. That is, in FIG. 2C, the adhesive 50 is arranged in the region along each of the four sides of the quadrilateral peripheral region 130. When the adhesive 50 containing a spacer with high size uniformity surrounds the plurality of elements 110 as shown in FIG. 2C, it is possible to maintain the constant spatial interval between the first surface 101 and the third surface 301, and protect the plurality of elements 110 from the external environment.

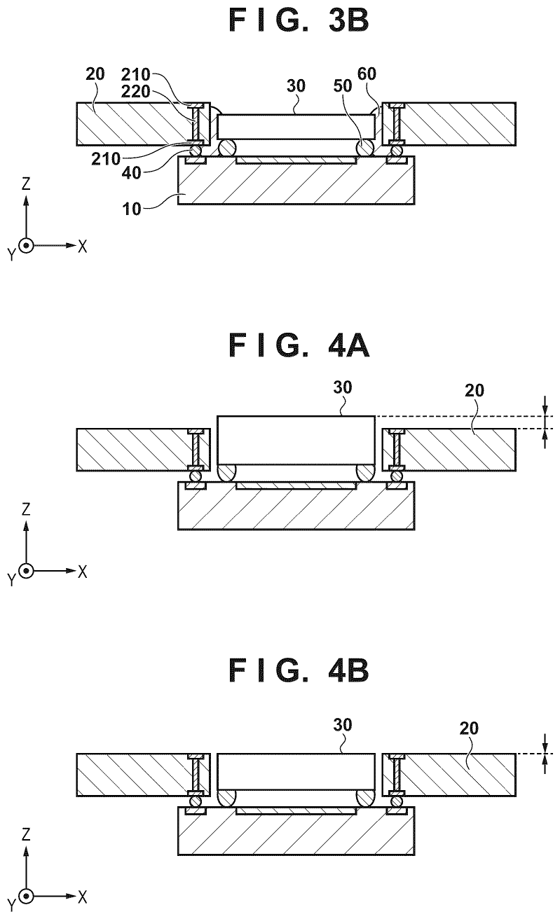

The gap between the optical member 30 and the circuit board 20 may be a space, or the gap may be filled with a resin. When the gap is filled with a resin, the bonding strength of the optical member 30 and the circuit board 20 to the substrate 10 can be improved. FIGS. 3A and 3B are sectional views of the electronic component 100 similar to FIG. 1B, showing different examples of formation of a resin 60. FIG. 3A shows an example in which, when bonding the optical member 30 and the substrate 10, the adhesive 50 as the resin 60 is injected into the gap so as to protrude to the lower surfaces of the optical member 30 and the circuit board 20, thereby filling the gap with the circuit board 20. FIG. 3B shows an example in which, after bonding the optical member 30 and the substrate 10 with the adhesive 50, the resin 60 as the same material as or different material from the adhesive 50 is additionally injected, thereby filling the gap with the circuit board 20.

Each of FIGS. 4A to 4C is a sectional view of the electronic component 100 similar to FIG. 1B, and showing an example of the height relationship between the optical member 30 and the circuit board 20. FIG. 4A shows an example in which the optical member 30 is at a higher position than the circuit board 20. FIG. 4B shows an example in which the optical member 30 is at the same height as the circuit board 20. FIG. 4C shows an example in which the optical member 30 is at a lower position than the circuit board 20. To miniaturize the electronic component 100, the optical member 30 is preferably at the same height as the circuit board 20 as shown in FIG. 4B, or the optical member 30 is preferably at a lower position than the circuit board 20 as shown in FIG. 4C. That is, the height of the optical member 30 is preferably equal to or lower than the height of the circuit board 20. When the optical member 30 is lower than the circuit board 20, this is advantageous in that when attaching the electronic component 100 to another component or the like via the opposite surface 202 of the second surface of the circuit board 20, a contact between the other component and the optical member 30 can be prevented.

The arrangements according to various examples described above are advantageous in miniaturization of the electronic component 100 as compared with the arrangement in which the substrate 10 is mounted on the circuit board 20 and the optical member 30 is mounted on the substrate 10, and the arrangement in which the circuit board 20 is mounted on the substrate 10 and the optical member 30 is mounted on the circuit board 20. Furthermore, when mounting the substrate 10 on the circuit board 20, the substrate 10 can warp due to thermal curing of the substrate 10 during bonding, and this can cause variations in the spatial distance from the optical member 30 mounted on the substrate 10. However, the arrangement according to this embodiment reduces warping of the substrate 10 so that variations in the spatial distance between the substrate 10 and the optical member 30 can be suppressed.

From above, according to this embodiment, an electronic component achieving both miniaturization and highly accurate alignment between an element in a substrate and an optical member can be provided.

### Second Embodiment

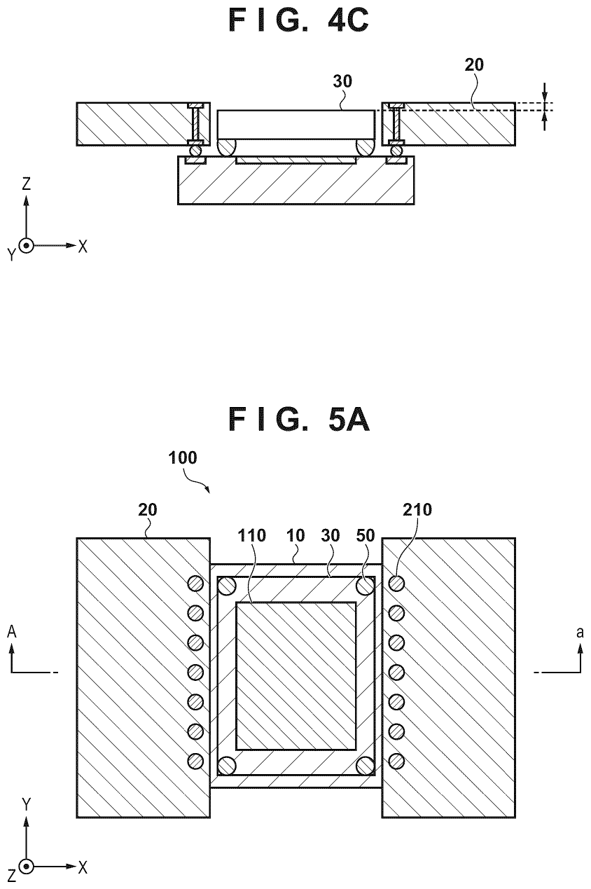

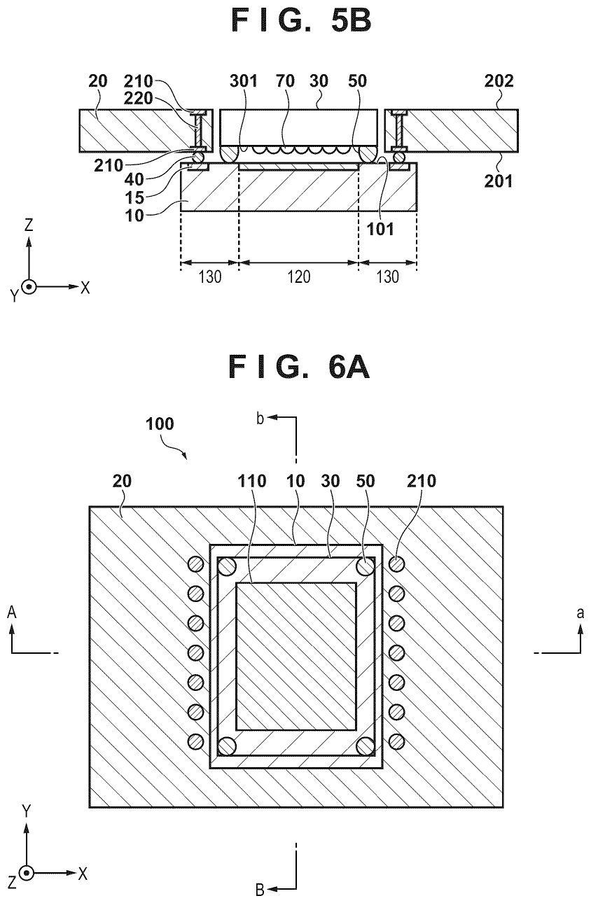

The second embodiment is different from the above-described first embodiment mainly in the arrangement of an optical member 30. Matters not mentions in the second embodiment can follow the first embodiment unless any contradiction occurs. FIGS. 5A and 5B are views showing the arrangement of an electronic component 100 according to the second embodiment. FIG. 5A is a plan view of the electronic component 100, and FIG. 5B is a sectional view taken along a line A-a shown in FIG. 5A.

As shown in FIG. 5B, a plurality of microlenses 70 are formed on a third surface 301 of the optical member 30. Each of the plurality of microlenses 70 is formed to match the size of each of a plurality of elements 110 formed in a substrate 10. The plurality of microlenses 70 are formed at the same pitch and in the same array as the plurality of elements 110, and the number of the plurality of microlenses 70 is at least equal to the number of the plurality of elements 110. Thus, each of the plurality of microlenses 70 is arranged at a position corresponding to each of the plurality of elements 110.

Each of the plurality of microlenses 70 can be formed by, for example, processing silica glass. When mounting the optical member 30 on the substrate 10, it is mounted such that each of the plurality of elements 110 and each of the plurality of microlenses 70 match in the XY position. Alignment between the plurality of elements 110 and the plurality of microlenses 70 is performed by, for example, providing alignment marks on the substrate 10 and the optical member 30 and recognizing the both alignment marks by an alignment scope (camera) (not shown). The distance between the optical member 30 and the substrate 10 is as described in the first embodiment. However, since the microlens 70 can improve the light condensing property, variations in the distance between the optical member 30 and the substrate 10 can be suppressed.

According to the second embodiment, the electronic component 100 achieving both miniaturization and highly accurate alignment between an element in a substrate and an optical member (microlens) can be provided.

### Third Embodiment

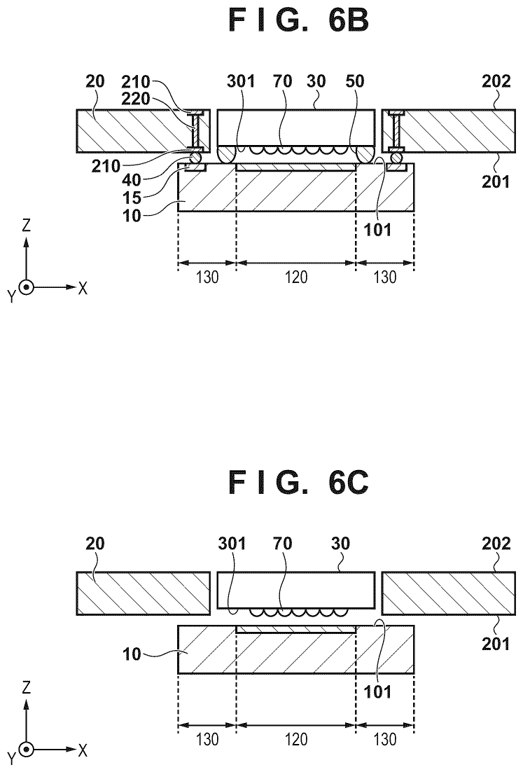

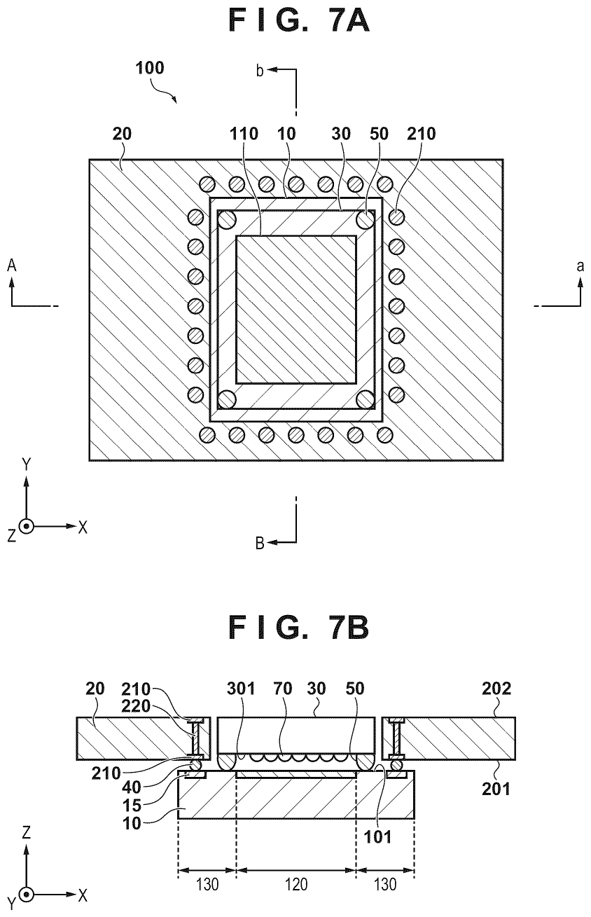

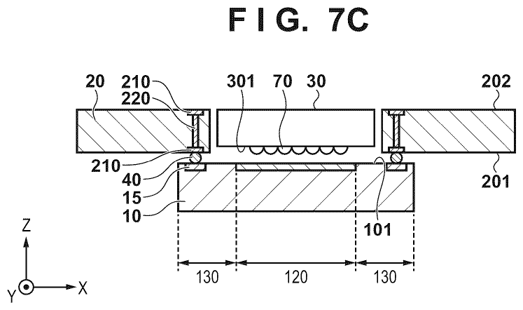

The third embodiment is different from the first and second embodiments mainly in the arrangement of a circuit board 20. Matters not mentioned in the third embodiment can follow the first and second embodiments unless any contradiction occurs. FIGS. 6A to 6C and FIGS. 7A to 7C are views each showing the arrangement of an electronic component 100 according to the third embodiment. FIGS. 6A and 7A are plan views of the electronic component 100. FIGS. 6B and 7B are sectional views taken along a line A-a shown in FIGS. 6A and 7A, respectively. FIGS. 6C and 7C are sectional views taken along a line B-b shown in FIGS. 6A and 7A, respectively.

The circuit board 20 has a shape having an opening at least above a central region 120 of a substrate 10. In the planar view of FIG. 6A, the circuit board 20 is arranged to surround the central region 120 of the substrate 10 that is visible from the opening. Since the circuit board 20 is one substrate, the circuit board 20 only needs to be mounted on the substrate 10 once. In addition, the area of the circuit board 20 on the substrate 10 is larger than that of the circuit board 20 in the first embodiment, so that the area where a wiring 220 can be arranged increases. Thus, the outer size of the circuit board 20 can be reduced. Note that in this example, as can be seen from FIGS. 6A to 6C, the substrate 10 and the circuit board 20 are electrically connected via the wiring 220 at a plurality of positions along two sides forming long sides of the opening.

The example shown in FIGS. 7A to 7C is the same as the example shown in FIGS. 6A to 6C in that the circuit board 20 has a shape with an opening above the central region 120 of the substrate 10. However, the example shown in FIGS. 7A to 7C is different from the example shown in FIG. 6A to 6C in that the substrate 10 and the circuit board 20 are electrically connected with the wiring 220 at a plurality of positions along four sides of the opening. Since the substrate 10 and the circuit board 20 are electrically connected at a plurality of positions along the four sides, electrodes are arranged along the four sides of a first surface 101 of the substrate 10. In this case, as compared to a case where electrodes are arranged only along two sides, miniaturization of the substrate 10 and miniaturization of the circuit board 20 can be achieved. In addition, in the arrangement shown in FIGS. 7A to 7C, since the substrate 10 and the circuit board 20 are connected in a region along the four sides, the mechanical strength can be improved.

According to this embodiment, the electronic component 100 achieving both miniaturization and highly accurate alignment between an element in a substrate and an optical member (microlens) can be provided. Note that the specific arrangement of the electronic component 100 is not limited to the above-described embodiments, and various modifications are possible. For example, in addition to that the wiring 220 extends through the second surface 201 and the opposite surface 202 of the circuit board 20 in the Z direction, if the substrate 20 is formed from a plurality of wiring layers, the wiring 220 can be routed also in the X and Y directions, and a wiring pattern with a plurality of paths is possible. It is also possible to combine all or some of the different embodiments described above.

Application examples of the above-described electronic component 100 will be described below as the fourth to tenth embodiments.

### Fourth Embodiment

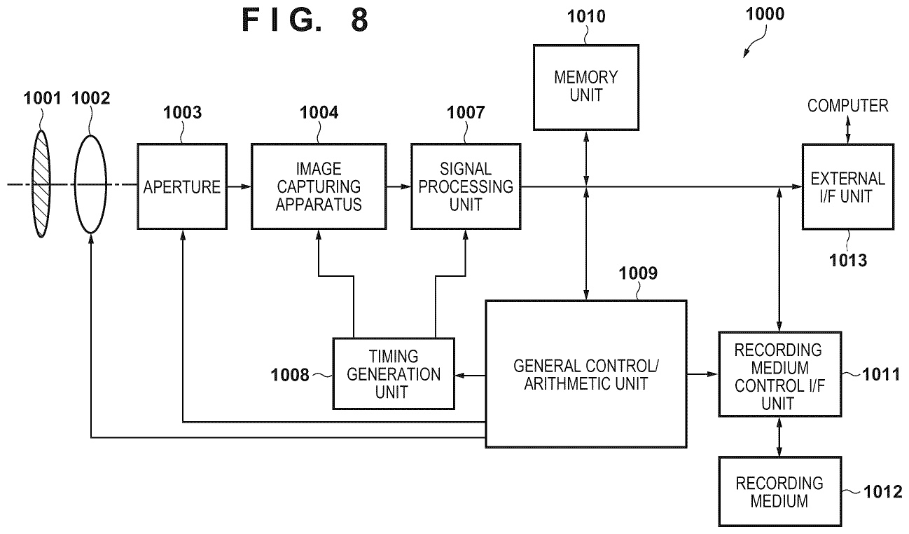

A system according to the fourth embodiment will be described with reference to FIG. 8. FIG. 8 is a block diagram showing the schematic arrangement of the system according to the fourth embodiment.

The electronic component 100 described above is applicable to various systems. Examples of the applicable system are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the system. FIG. 8 exemplarily shows the block diagram of a digital still camera as an example of these.

A system 1000 exemplarily shown in FIG. 8 includes an image capturing apparatus 1004 as an example of the electronic component. The system 1000 also includes a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 includes the above-described electronic component 100 (image capturing apparatus) with the element 110 as a light-receiving element, and converts the optical image formed by the lens 1002 into an electrical signal.

The system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The system 1000 further includes a memory unit 1010 configured to temporarily store image data, and an external interface unit (external I/F unit) 1013 configured to communicate with an external computer or the like. Furthermore, the system 1000 includes a recording medium 1012 such as a semiconductor memory configured to record or read out image capturing data, and a recording medium control interface unit (recording medium control I/F unit) 1011 configured to perform record or readout for the recording medium 1012. The recording medium control I/F unit 1011 and the recording medium 1012 can form a part of a recording apparatus. Note that the recording medium 1012 may be incorporated in the system 1000 or may be detachable.

Furthermore, the system 1000 includes a general control/arithmetic unit 1009 that controls various kinds of operations and the entire digital still camera, and a timing generation unit 1008 that outputs various kinds of timing signals to the image capturing apparatus 1004 and the signal processing unit 1007. The general control/arithmetic unit 1009 and the timing generation unit 1008 can form a part of a control apparatus configured to control an operation of the system 1000. In this example, the timing signal and the like may be input from the outside, and the system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 8, a display apparatus such as a display for displaying the generated image may be arranged in the system 1000. As described above, according to this embodiment, it is possible to implement the system 1000 to which the electronic component 100 (image capturing apparatus) according to one of the above-described embodiments is applied.

### Fifth Embodiment

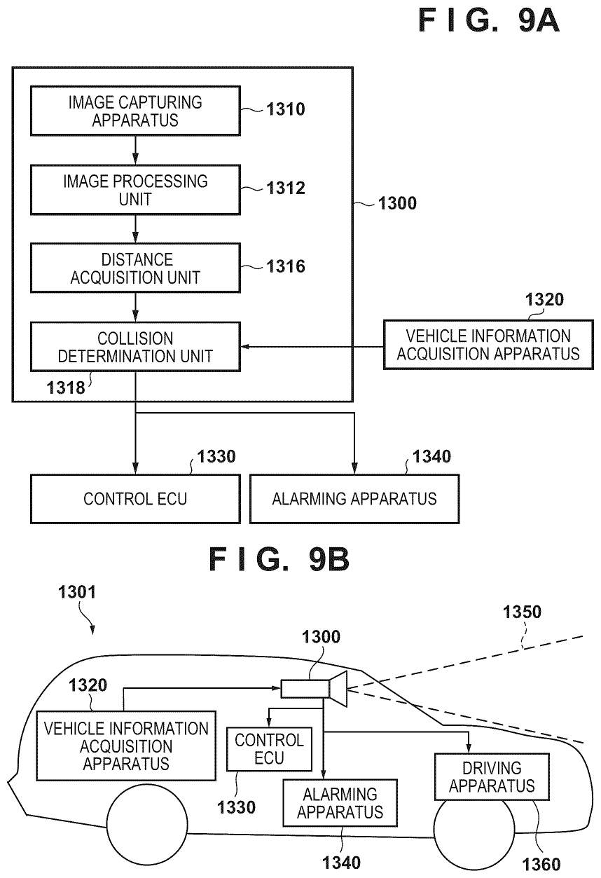

A system 1300 and a moving body 1301 according to the fifth embodiment will be described with reference to FIGS. 9A and 9B. FIGS. 9A and 9B are views showing the arrangement of the system 1300 and the moving body 1301 according to the fifth embodiment.

FIG. 9A shows an example of a system concerning an in-vehicle camera. The system 1300 includes an image capturing apparatus 1310. The image capturing apparatus 1310 is the above-described electronic component 100 (image capturing apparatus) with the element 110 as a light-receiving element. The system 1300 includes an image processing unit 1312 that performs image processing for a plurality of image data acquired by the image capturing apparatus 1310. The system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like. The distance acquisition unit 1316 may be implemented by a combination of these.

The system 1300 is connected to a vehicle information acquisition apparatus 1320, and can acquire vehicle information such as a vehicle speed, a yaw rate, and a steering angle. The system 1300 is also connected to an ECU 1330 that is a control apparatus configured to output a control signal for generating a braking force to the vehicle based on the determination result of the collision determination unit 1318. Furthermore, the system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (machine apparatus) 1360 to perform braking, releasing the accelerator pedal, or suppressing the engine output, thereby controlling the vehicle for avoiding collision and reducing damage. The alarm apparatus 1340 sounds an alarm, displays alarm information on the screen of a car navigation system or the like, or applies a vibration to the seat belt or a steering wheel, thereby making an alarm to the user.

In this embodiment, the periphery of the vehicle (moving body 1301), for example, the front or rear side is captured by the system 1300. FIG. 9B shows the system when capturing the front side (image capturing range 1350) of the vehicle. The vehicle information acquisition apparatus 1320 sends an instruction to the system 1300 or the image capturing apparatus 1310. With this arrangement, it is possible to further improve the accuracy of distance measurement.

An example in which control is executed so as not to collide with another vehicle has been explained above. The system 1300 can also be applied to control of performing automated driving following another vehicle or control of performing automated driving without deviating from a lane. Furthermore, the system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller, or the like. In addition, the system can be applied not only to a moving body but also to equipment that broadly uses object recognition, such as an intelligent transport system (ITS).

### Sixth Embodiment

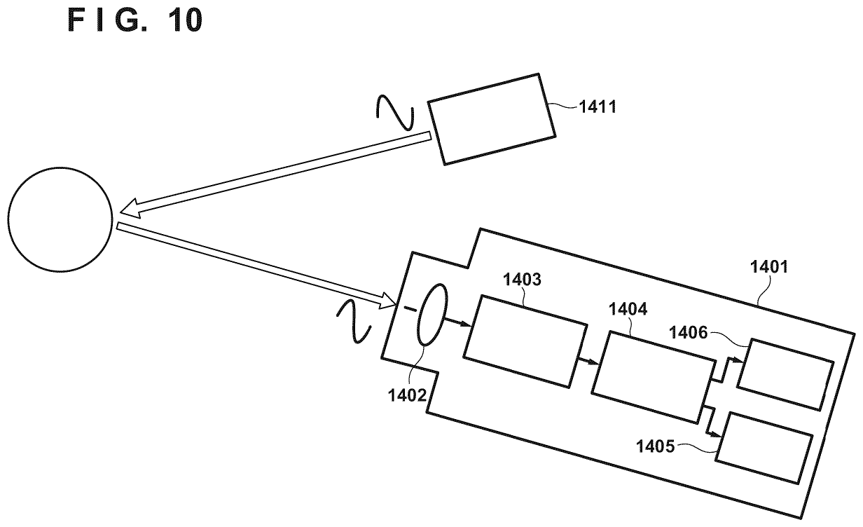

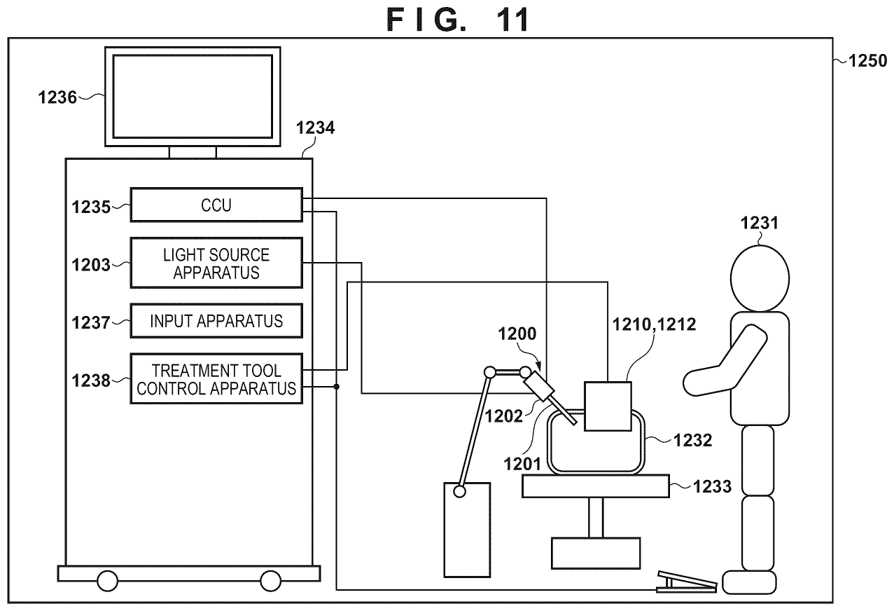

A system according to the sixth embodiment will be described with reference to FIG. 10. FIG. 10 is a block diagram showing an example of the arrangement of a distance image sensor 1401 as the system according to this embodiment.

As shown in FIG. 10, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion apparatus 1403 and forms an image on the light-receiving surface (sensor portion) of the photoelectric conversion apparatus 1403.

As the photoelectric conversion apparatus 1403, the above-described electronic component 100 with the element 110 as a light-receiving element is applied, and a distance signal indicating a distance obtained from a light reception signal output from the photoelectric conversion apparatus 1403 is supplied to the image processing circuit 1404.

The image processing circuit 1404 performs image processing of creating a distance image based on the distance signal supplied from the photoelectric conversion apparatus 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described electronic component 100.

### Seventh Embodiment

A system according to the seventh embodiment will be described with reference to FIG. 11. FIG. 11 is a view showing an example of the schematic arrangement of an endoscopic surgery system 1250 as the system according to this embodiment.

FIG. 11 shows a state in which an operator (doctor) 1231 operates on a patient 1232 on a patient bed 1233 using the endoscopic surgery system 1250. As shown in FIG. 11, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 11, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is condensed by the optical system to the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the above-described electronic component 100 (image capturing apparatus) with the element 110 as a light-receiving element can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. The light source apparatus 1203 can use the above-described electronic component 100 with the element 110 as a light-emitting element. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss and highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing irradiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

### Eighth Embodiment

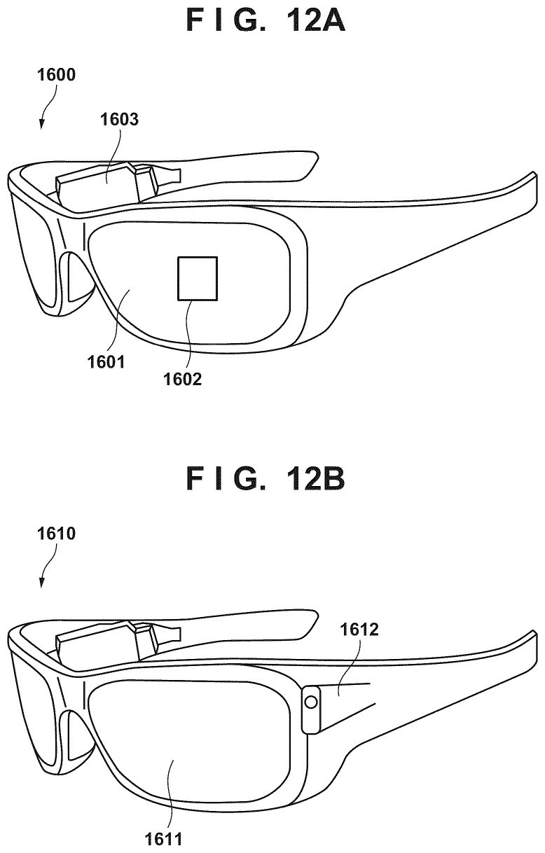

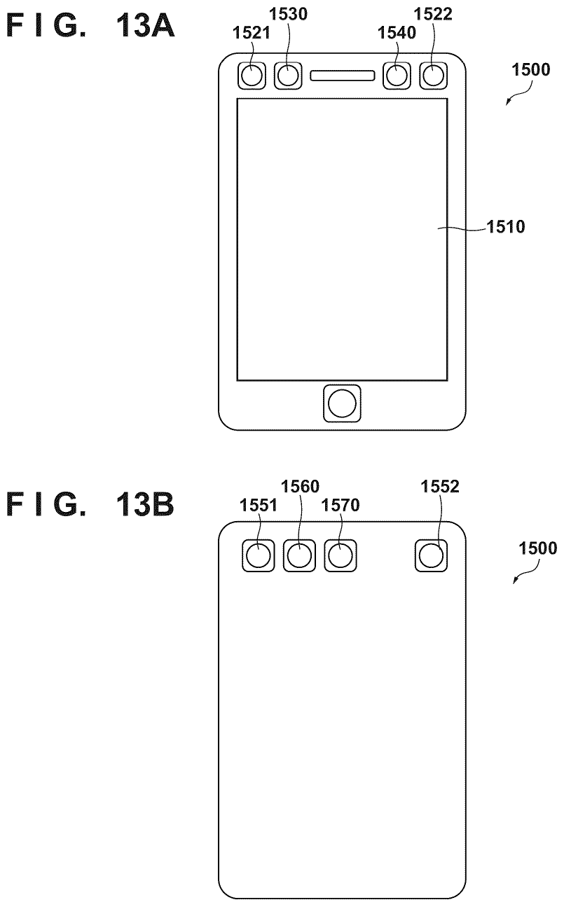

A system according to the eighth embodiment will be described with reference to FIGS. 12A and 12B. FIG. 12A describes glasses 1600 (smartglasses) as the system according to this embodiment. The glasses 1600 include a photoelectric conversion apparatus 1602. The photoelectric conversion apparatus 1602 is the above-described electronic component 100 (image capturing apparatus) with the element 110 as a light-receiving element. A display apparatus including the light-emitting apparatus such as an OLED or LED may be provided on the back surface side of a lens 1601. If the light-emitting apparatus is an LED, the light-emitting apparatus can use the above-described electronic component 100 with the element 110 as a light-emitting element. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 12A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 12B describes glasses 1610 (smartglasses) according to an application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light-receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to the embodiment can include a photoelectric conversion apparatus including a light-receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

When performing display control based on line-of-sight detection, smartglasses further including a photoelectric conversion apparatus configured to capture the image of the outside can preferably be applied. The smartglasses can display the captured outside image information in real time.

### Ninth Embodiment

The ninth embodiment will be described with reference to FIGS. 13A and 13B. The above-described photoelectric conversion apparatus and system may be applied to, for example, electronic equipment such as a so-called smartphone or tablet.

FIGS. 13A and 13B are views showing an example of electronic equipment 1500 on which the photoelectric conversion apparatus is mounted. FIG. 13A shows the front surface side of the electronic equipment 1500, and FIG. 13B shows the back surface side of the electronic equipment 1500.

As shown FIG. 13A, a display 1510 that displays an image is arranged at the center of the front surface of the electronic equipment 1500. Then, front cameras 1521 and 1522, an IR light source 1530 that emits infrared rays, and a visible light source 1540 that emits visible light are arranged along the upper side of the front surface of the electronic equipment 1500. For the front cameras 1521 and 1522, the above-described electronic component 100 with the element 110 as a light-receiving element can be used. For the IR light source 1530 and the visible light source 1540, the above-described electronic component 100 with the element 110 as a light-emitting element can be used.

As shown in FIG. 13B, rear cameras 1551 and 1552, an IR light source 1560 that emits infrared rays, and a visible light source 1570 that emits visible light are arranged along the upper side of the back surface of the electronic equipment 1500. For the rear cameras 1551 and 1552, the above-described electronic component 100 with the element 110 as a light-receiving element can be used. For the IR light source 1560 and the visible light source 1570, the above-described electronic component 100 with the element 110 as a light-emitting element can be used.

By applying the above-described electronic component 100, the electronic equipment 1500 having the above arrangement can capture, for example, an image of higher quality. Note that the photoelectric conversion apparatus can be applied to electronic equipment such as an infrared sensor, a distance measurement sensor using an active infrared source, a security camera, or a personal or biometric authentication camera. This can improve the accuracy and performance of the electronic equipment.

### Tenth Embodiment

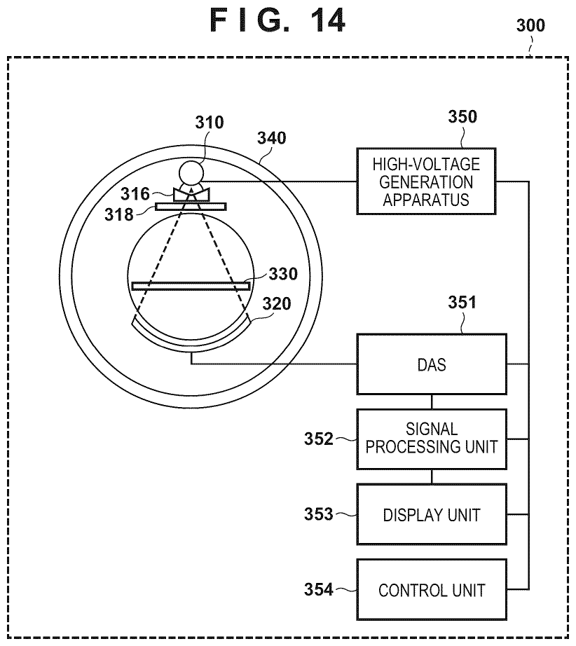

FIG. 14 is a block diagram of an X-ray CT apparatus 300 according to the tenth embodiment. The above-described electronic component 100 is applicable to a detector of the X-ray CT apparatus 300. The X-ray CT apparatus 300 according to this embodiment includes an X-ray generation unit 310, a wedge 316, a collimator 318, an X-ray detection unit 320, a top plate 330, a rotating frame 340, and a high-voltage generation apparatus 350. The X-ray CT apparatus 300 also includes a Data Acquisition System (DAS) 351, a signal processing unit 352, a display unit 353, and a control unit 354.

The X-ray generation unit 310 is formed from, for example, a vacuum tube that generates X-rays. The vacuum tube of the X-ray generation unit 310 is supplied with a filament current and a high voltage from the high-voltage generation apparatus 350. When thermoelectrons are emitted from a cathode (filament) to an anode (target), X-rays are generated.

The wedge 316 is a filter that adjusts the amount of X-rays emitted from the X-ray generation unit 310. The wedge 316 attenuates the amount of X-rays so that the X-rays emitted from the X-ray generation unit 310 to an object has a predetermined distribution. The collimator 318 is formed from a lead plate that narrows the irradiation range of the X-rays having passed through the wedge 316. The X-rays generated by the X-ray generation unit 310 is formed in a cone beam shape via the collimator 318, and the object on the top plate 330 is irradiated with the X-rays.

The X-ray detection unit 320 is formed using the above-described electronic component 100 with the element 110 as a light-receiving element. The X-ray detection unit 320 detects the X-rays having passed through the object from the X-ray generation unit 310, and outputs a signal corresponding to the amount of the X-rays to the DAS 351.

The rotating frame 340 is annular, and is configured to be rotatable. The X-ray generation unit 310 (the wedge 316 and the collimator 318) and the X-ray detection unit 320 are arranged to face each other in the rotating frame 340. The X-ray generation unit 310 and the X-ray detection unit 320 can rotate together with the rotating frame 340.

The high-voltage generation apparatus 350 includes a boosting circuit, and outputs a high voltage to the X-ray generation unit 310. The DAS 351 includes an amplification circuit and an A/D conversion circuit, and outputs, as digital data, a signal from the X-ray detection unit 320 to the signal processing unit 352.

The signal processing unit 352 includes a Central Processing Unit (CPU), a Read Only Memory (ROM), and a Random Access Memory (RAM), and can execute image processing and the like for the digital data. The display unit 353 includes a flat display apparatus or the like, and can display an X-ray image. The control unit 354 includes a CPU, a ROM, a RAM, and the like, and controls the operation of the overall X-ray CT apparatus 300.

The present invention is not limited to the above embodiments and various changes and modifications can be made within the spirit and scope of the present invention. Therefore, to apprise the public of the scope of the present invention, the following claims are made.

According to the present disclosure, a technique advantageous in achieving both miniaturization of an electronic component and highly accurate alignment between an element in a substrate and an optical member can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-013305, filed Jan. 31, 2024, which is hereby incorporated by reference herein in its entirety.

What is claimed is:

1. An electronic component comprising a substrate having a first surface, a circuit board having a second surface facing the first surface, and an optical member having a third surface facing the first surface, wherein
the first surface of the substrate has a central region where a plurality of elements are arranged,
the second surface of the circuit board is arranged above the first surface so as not to cover the central region,
the third surface of the optical member is arranged above the central region without intervening the circuit board so as to have a space between the first surface and the third surface, and
a plurality of microlenses are arranged on the third surface of the optical member.

2. The component according to claim 1, wherein the circuit board has an opening at least above the central region.

3. The component according to claim 1, further comprising:
a first electrode arranged in the first surface of the substrate; and
a second electrode arranged in the second surface of the circuit board,
wherein the first electrode and the second electrode are electrically connected via an electrically conductive member.

4. The component according to claim 3, wherein
the second electrode includes a plurality of second electrodes arranged in the second surface of the circuit board, and
the component further comprises a plurality of third electrodes arranged in an opposite surface of the second surface of the circuit board and configured to be electrically connected to the plurality of second electrodes.

5. The component according to claim 1, wherein the plurality of microlenses have the same array as the plurality of elements.

6. The component according to claim 5, wherein each of the plurality of microlenses is arranged at a position corresponding to each of the plurality of elements.

7. The component according to claim 1, wherein the first surface of the substrate and the third surface of the optical member are bonded with an adhesive.

8. The component according to claim 7, wherein the adhesive contains a spacer of a uniform size.

9. The component according to claim 7, wherein the adhesive is arranged at at least four locations scattered in a peripheral region located around the central region of the substrate.

10. The component according to claim 7, wherein the adhesive is arranged in a first region having a longitudinal length in a direction along a first side of a quadrilateral peripheral region located around the central region of the substrate and in a second region having a longitudinal length in direction along a second side located on an opposite side of the first side.

11. The component according to claim 7, wherein the adhesive is arranged in a region along each of four sides of a quadrilateral peripheral region located around the central region of the substrate.

12. The component according to claim 1, wherein an interval between the first surface of the substrate and the third surface of the optical member is not less than 10 μm and not more than 200 μm.

13. The component according to claim 1, wherein a gap is provided between the optical member and the circuit substrate.

14. The component according to claim 13, further comprising a resin filling the gap.

15. The component according to claim 1, wherein a height of the optical member is not more than a height of the circuit board.

16. The component according to claim 1, wherein each of the plurality of elements is a light-receiving element.

17. The component according to claim 1, wherein each of the plurality of elements is a light-emitting element.

18. A system comprising:
an electronic component defined in claim 16; and
a signal processing unit configured to process a signal output from the electronic component.

19. A system comprising:
a signal processing unit configured to process a signal; and
a display apparatus configured to display, by using an electronic component defined in claim 17, information based on the signal processed by the signal processing unit.

20. A moving body that includes an electronic component defined in claim 16, comprising
a control unit configured to control movement of the moving body using a signal output from the electronic component.
